(19) United States
(12) Patent Application Publication
(10) Pub. No.: US 2024/0412981 A1
(43) Pub. Date: Dec. 12, 2024

(54) SELECTIVE RUTHENIUM DEPOSITION AND RELATED SYSTEMS AND METHODS

(71) Applicant: ENTEGRIS, INC., Billerica, MA (US)

(72) Inventors: Phil S.H. Chen, Bethel, CT (US); Bryan C. Hendrix, Danbury, CT (US); Eric Condo, Shelton, CT (US)

(21) Appl. No.: 18/737,743

(22) Filed: Jun. 7, 2024

Related U.S. Application Data
(60) Provisional application No. 63/472,158, filed on Jun. 9, 2023.

(51) Int. Cl. H01L 21/3205; C23C 16/04; C23C 16/06; C23C 16/448; H01L 23/532

(52) U.S. Cl. CPC H01L 21/32051; C23C 16/04; C23C 16/06; C23C 16/4485; H01L 23/53257

(57) ABSTRACT

Selective ruthenium deposition and related systems and methods are provided. A method comprises vaporizing at least a portion of a ruthenium precursor to produce a vaporized ruthenium precursor; contacting a first surface portion and a second surface portion of a substrate with the vaporized ruthenium precursor and at least one reducing gas; and depositing ruthenium on the first surface portion of the substrate with a selectivity of at least 25 Å relative to the second surface portion of the substrate. A device comprises a substrate having a first surface portion and a second surface portion adjacent to the first surface portion; and a ruthenium layer located on the first surface portion of the substrate, wherein the ruthenium layer has a thickness of at least 25 Å on the first surface portion of the substrate; wherein the second surface portion of the substrate does not comprise ruthenium.

### CROSS-REFERENCE TO RELATED APPLICATIONS

This application claims the benefit under 35 USC 119 of U.S. Provisional Patent Application No. 63/472,158, filed Jun. 9, 2023, the disclosure of which is hereby incorporated herein by reference in its entirety.

### FIELD

The present disclosure relates to selective deposition of ruthenium and related systems and methods.

### BACKGROUND

Conventional processes for depositing ruthenium films require multiple steps. In addition, conventional processes deposit ruthenium using O₂ as a co-reactant, which is undesirable because the O₂ oxidizes the substrate during the deposition process. Depositing ruthenium with high selectivity remains an ongoing challenge.

### SUMMARY

Some embodiments relate to a method for selective deposition of ruthenium. In some embodiments, the method for selective deposition of ruthenium comprises vaporizing at least a portion of a ruthenium precursor to produce a vaporized ruthenium precursor. In some embodiments, the method for selective deposition of ruthenium comprises contacting a first surface portion and a second surface portion of a substrate with the vaporized ruthenium precursor and at least one reducing gas. In some embodiments, the method for selective deposition of ruthenium comprises depositing ruthenium on the first surface portion of the substrate with a selectivity of at least 25 Å relative to the second surface portion of the substrate.

Some embodiments relate to a device. In some embodiments, the device comprises a substrate. In some embodiments, the substrate has a first surface portion and a second surface portion adjacent to the first surface portion. In some embodiments, the device comprises a ruthenium layer located on the first surface portion of the substrate. In some embodiments, the ruthenium layer has a thickness of at least 25 Å on the first surface portion of the substrate. In some embodiments, the second surface portion of the substrate does not comprise ruthenium.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for making a ruthenium-containing film 100, according to some embodiments.

FIG. 2 is a graphical view of ruthenium film thickness versus atomic layer deposition cycle, according to some embodiments.

FIG. 3 is a graphical view of ruthenium film thickness versus atomic layer deposition cycle, according to some embodiments.

FIG. 4 is a graphical view of ruthenium film thickness versus atomic layer deposition cycle, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may.

Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise.

In addition, throughout the specification, the meaning of “a,” “an,” and “the” include plural references. The meaning of “in” includes “in” and “on.”

As used herein, the term “alkyl” refers to a hydrocarbon compound having from 1 to 30 carbon atoms. An alkyl having n carbon atoms may be designated as a “Ca alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₅-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof.

Some embodiments relate to depositing ruthenium on substrates with high selectivity. In some embodiments, ruthenium is selectively deposited on a surface of the substrate as a thin film via atomic layer deposition processes, such as, for example and without limitation, plasma-enhanced atomic layer deposition, thermal atomic layer deposition, and the like. At least one advantage of the embodiments disclosed herein is that ruthenium can be deposited on a desired surface with a selectivity of up to 80 Å. At least another advantage of the embodiments disclosed herein is that the deposition process free or substantially free of oxygen. At least a further advantage of the embodiments disclosed herein is that the ruthenium is deposited at temperatures of 450° C. or less. At least an additional advantage of the embodiments disclosed herein is that the ruthenium is selectively deposited on, for example and without limitation, surfaces other than silicon oxide, thermal oxide, silicon nitride, SiCOH, low k dielectric, porous low k dielectrics and/or polysilicon. These shall not be limiting as other advantages of the embodiments disclosed herein will become apparent upon review of this disclosure.

As used herein, the term “selectivity,” when described with respect to a thickness (e.g., a thickness in units of A), refers to a maximum thickness of a substance on a first surface before the substance is deposited on a surface other than the first surface. For example, depositing ruthenium on a first surface of a substrate with a selectivity of 80 Å means that, when a thickness of the ruthenium on the first surface of the substrate exceeds 80 Å, the ruthenium will begin to be deposited on a surface other than the first surface (e.g., a second surface).

As used herein, the term “substantially free” refers to an amount of no greater than 5% by weight or by volume of a substance based on a total weight or a total volume. In some embodiments, the term “substantially free” refers to no greater than 4%, no greater than 3%, no greater than 2%, no greater than 1%, no greater than 0.9%, no greater than 0.8%, no greater than 0.7%, no greater than 0.6%, no greater than 0.5%, no greater than 0.4%, no greater than 0.3%, no greater than 0.2%, or no greater than 0.1% by weight or by volume of a substance based on a total weight or a total volume. In some embodiments, the term “substantially free” refers to an amount that is not detectable (e.g., an undetectable amount) using standard equipment. As used herein, the term “free” refers to an amount of a substance in which the substance is not present.

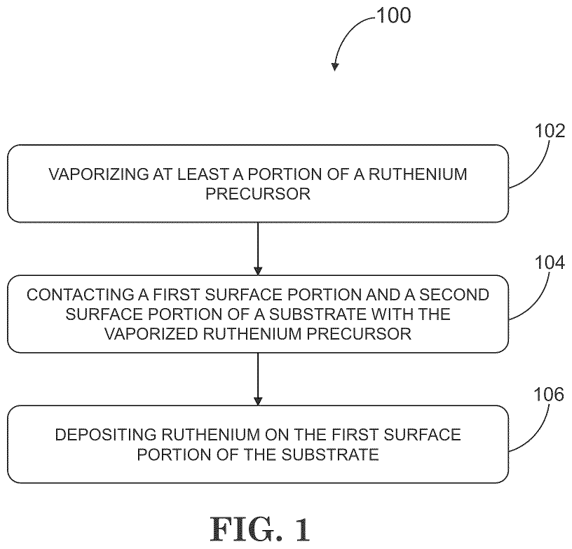

FIG. 1 is a flowchart of a method for making a ruthenium-containing film 100, according to some embodiments. As shown in FIG. 1, the method for making the ruthenium-containing film 100 comprises one or more of the following steps: vaporizing 102 at least a portion of a ruthenium precursor to produce a vaporized ruthenium precursor; contacting 104 a first surface portion and a second surface portion of a substrate with the vaporized ruthenium precursor and at least one reducing gas; and depositing 106 ruthenium on the first surface portion of the substrate with a selectivity of at least 25 Å relative to the second surface portion of the substrate. In some embodiments, the method for making a ruthenium-containing film 100 is an atomic layer deposition (ALD) process. In some embodiments, the method for making a ruthenium-containing film 100 is a plasma-enhanced atomic layer deposition (PEALD) process. In some embodiments, the method for making a ruthenium-containing film 100 is thermal atomic layer deposition (thermal ALD) process.

The method for making a ruthenium-containing film 100 may comprise vaporizing 102 at least a portion of a ruthenium precursor to produce a vaporized ruthenium precursor.

In some embodiments, the vaporizing may comprise heating the ruthenium precursor sufficient to obtain the vaporized ruthenium precursor. In some embodiments, the vaporizing may comprise heating a vessel containing the ruthenium precursor. In some embodiments, the ruthenium precursor is present in at least one of a liquid phase, a gas phase, a vapor phase, a solid phase, or any combination thereof. In some embodiments, the vaporizing may comprise heating the ruthenium precursor in a deposition chamber in which the vapor deposition process is performed. In some embodiments, the vaporizing may comprise heating a conduit for delivering the ruthenium precursor, vaporized ruthenium precursor, or any combination thereof to, for example, a deposition chamber. In some embodiments, the vaporizing may comprise operating a vapor delivery system comprising the ruthenium precursor. In some embodiments, the vaporizing may comprise heating to a temperature sufficient to vaporize the ruthenium precursor to obtain the vaporized ruthenium precursor. In some embodiments, the vaporizing may comprise heating to a temperature below a decomposition temperature of at least one of the ruthenium precursor, the vaporized ruthenium precursor, or any combination thereof. In some embodiments, the ruthenium precursor may be present in a gas phase, in which case the step 102 is optional and not required.

For example, the ruthenium precursor may comprise the vaporized ruthenium precursor.

In some embodiments, the ruthenium precursor is a precursor of the formula:

R¹R²Ru(0),
wherein R¹ is benzene or an aryl group-containing ligand, and R² is a diene group-containing ligand.

As used herein, an “aryl group-containing ligand” includes at least one aromatic ring with one or more hydrocarbon substituents attached to the aromatic ring. For example, in some embodiments, the aryl group-containing ligand can be a monoalkylbenzene, a dialkylbenzene, or a trialkylbenzene, or a fused ring structure such as indane and/or tetrahydronaphthalene (e.g., benzocyclohexane, tetralin).

As used herein, a “diene group-containing ligand” is a compound including at least two carbon-carbon double bonds separated by at least one carbon-carbon single bond, and can include conjugated dienes and unconjugated dienes. Diene group-containing ligands can optionally include more than two carbon-carbon double bonds, such as trienes and so on. Diene group-containing ligands include linear compounds and cyclic compounds. Cyclic diene group-containing ligands can have a single ring structure, such as cyclohexadiene, cyclohexadiene, or alkylated derivatives thereof, or can have a fused cyclic ring structure, such as hexahydronaphthalene, thetrahydroindene, dicyclopentadiene, or norbornadiene.

For example, in some embodiments, R¹ comprises at least one of toluene, xylene, ethylbenzene, cumene, cymene, or any combination thereof. In embodiments, R² comprises a cyclic unconjugated diene or linear unconjugated diene. In some embodiments, R² is cyclohexadiene or an alkylcyclohexadiene. In some embodiments, R² comprises at least one of cyclohexadiene, methylcyclohexadiene, ethylcyclohexadiene, propylcyclohexadiene, or any combination thereof.

In some embodiments, the ruthenium precursor comprises compounds of the formula II:

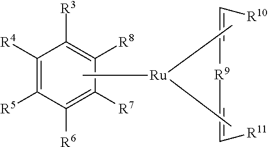

wherein:
R³-R⁸ are each independently a hydrogen or a C₁-C₆ alkyl;
R⁹ is a covalent bond or a divalent alkene group of 1-4 carbon atoms; and
R¹⁰ and R¹¹ form one or more ring structures or are each independently a hydrogen or a C₁-C₆ alkyl. In some embodiments, one, two, or three of R³-R⁸ are selected from a C₁-C₆ alkyl or a C₁-C₃ alkyl, with the remaining R³-R⁸ being a hydrogen. In some embodiments, R⁹ is a covalent bond, and R¹⁰ and R¹¹ form one or more ring structures.

In some embodiments, the ruthenium precursor of the formula R¹ and R² does not comprise any heteroatoms (i.e., an atom other than carbon or hydrogen). For example, in some embodiments, R¹ and R² can consist of carbon and hydrogen. In some embodiments, compounds of the formula R¹R²Ru(0) can also be described in terms of their degree of unsaturation, their total carbon atom content, their total hydrogen content, or combinations thereof.

In some embodiments, the ruthenium precursor of the formula R¹R²Ru(0) can have a total carbon atom amount in the range of (a1) 12 to 20, in the range of (a2) 14 to 18, or in the range of (a3) 15 to 17. In some embodiments, the ruthenium precursor has a total carbon atom amount of (a4) 16. The ruthenium precursor of the formula R¹R²Ru(0) can also have a total hydrogen atom amount in the range of (b1) 16 to 28, in the range of (b2) 19 to 25, or in the range of (b3) 20-24. In some embodiments, the ruthenium precursor has a total hydrogen atom amount of 22. In some embodiments, the ruthenium precursor can have combined carbon and hydrogen amounts of (a1) and (b1), (a2) and (b2), or (a3) and (b3).

In some embodiments, the ruthenium precursor comprises at least one of (cymene)(1,3-cyclohexadiene)Ru(0), (cymene)(1,4-cyclohexadiene)Ru(0), (cymene)(1-methylcyclohexa-1,3-diene)Ru(0), (cymene)(2-methylcyclohexa-1,3-diene)Ru(0), (cymene)(3-methylcyclohexa-1,3-diene)Ru(0), (cymene)(4-methylcyclohexa-1,3-diene)Ru(0), (cymene)(5-methylcyclohexa-1,3-diene)Ru(0), (cymene)(6-methylcyclohexa-1,3-diene)Ru(0), (cymene)(1-methylcyclohexa-1,4-diene)Ru(0), (cymene)(2-methylcyclohexa-1,4-diene)Ru(0), (cymene)(3-methylcyclohexa-1,4-diene)Ru(0), (cymene)(4-methylcyclohexa-1,4-diene)Ru(0), (cymene)(5-methylcyclohexa-1,4-diene)Ru(0), (cymene)(6-methylcyclohexa-1,4-diene)Ru(0), or any combination thereof. Cymene is also known as 1-Methyl-4-(propan-2-yl)benzene or 1-isopropyl-4-methylbenzene.

In some embodiments, the ruthenium precursor comprises at least one of (benzene)(1,3-cyclohexadiene)Ru(0), (toluene)(1,3-cyclohexadiene)Ru(0), (ethylbenzene)(1,3-cyclohexadiene)Ru(0), (1,2-xylene)(1,3-cyclohexadiene)Ru(0), (1,3-xylene)(1,3-cyclohexadiene)Ru(0), (1,4-xylene)(1,3-cyclohexadiene)Ru(0), (p-cymene)(1,3-cyclohexadiene)Ru(0), (o-cymene)(1,3-cyclohexadiene)Ru(0), (m-cymene)(1,3-cyclohexadiene)Ru(0), (cumene)(1,3-cyclohexadiene)Ru(0), (n-propylbenzene)(1,3-cyclohexadiene)Ru(0), (m-ethyltoluene)(1,3-cyclohexadiene)Ru(0), (p-ethyltoluene)(1,3-cyclohexadiene)Ru(0), (o-ethyltoluene)(1,3-cyclohexadiene)Ru(0), (1,3,5-trimethylbenzene)(1,3-cyclohexadiene)Ru(0), (1,2,3-trimethylbenzene)(1,3-cyclohexadiene)Ru(0), (tert-butylbenzene)(1,3-cyclohexadiene)Ru(0), (isobutylbenzene)(1,3-cyclohexadiene)Ru(0), (sec-butylbenzene)(1,3-cyclohexadiene)Ru(0), (indane)(1,3-cyclohexadiene)Ru(0), (1,2-diethylbenzene)(1,3-cyclohexadiene)Ru(0), (1,3-diethylbenzene)(1,3-cyclohexadiene)Ru(0), (1,4-diethylbenzene)(1,3-cyclohexadiene)Ru(0), (1-methyl-4-propylbenzene)(1,3-cyclohexadiene) Ru(0), (1,4-dimethyl-2-ethylbenzene)(1,3-cyclohexadiene)Ru(0), or any combination thereof.

In some embodiments, the ruthenium precursor comprises at least one of:

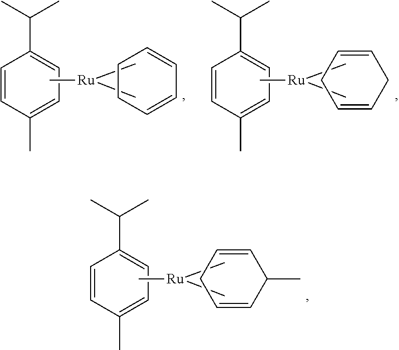

or
any combination thereof.

In some embodiments, the ruthenium precursors can also be described with reference to the melting and/or boiling point of the compound. In some embodiments, the ruthenium precursor is a liquid at room temperature (25° C.). In some embodiments, the ruthenium precursor may also have a boiling point in a temperature range of about 100° C. to about 175° C., or about 120° C. to about 150° C.

In some embodiments, if the ruthenium precursor of Formula I is in the form of a liquid at room temperature (25° C.), it can be described in terms of its vapor pressure. The vapor pressure of a liquid is the equilibrium pressure of a vapor above its liquid. The pressure of the vapor results from evaporation of the liquid as measured in a closed container at a certain temperature. For example, the precursor may have a vapor pressure at 100° C. of at least about 0.01 Torr, or at least about 0.05 Torr, such as in the range of about 0.05 Torr to about 0.50 Torr, or in the range of about 0.1 Torr to about 0.30 Torr.

In some embodiments, the ruthenium precursor is made by reacting a ruthenium-containing reactant, such as a ruthenium salt hydrate, with a first hydrocarbon-containing ligand (R1), forming an intermediate, and then reacting the intermediate with a second hydrocarbon-containing ligand (R2) to form the final product. For example, (6-1-isopropyl-4-methylbenzene)-(4-cyclohexa-1,3-diene)Ru(0) (IMBCHRu) can be made by preparing an ethanol solution of ruthenium trichloride hydrate and a-terpene, refluxing for 5 hours, to form a microcrystalline product of m-chloro-bis(chloro(1-isopropyl-4-methylbenzene)ruthenium(II)), which was then dried and then added to a solution of ethanol with Na₂CO₃, and 1,3-cyclohexadiene, and then refluxed for 4.5 hours.

The method for making a ruthenium-containing film 100 may comprise vaporizing at least a portion of at least one reducing agent to produce the at least one reducing gas.

In some embodiments, the vaporizing may comprise heating the at least one reducing agent sufficient to obtain the at least one reducing gas. In some embodiments, the vaporizing may comprise heating a vessel containing the at least one reducing agent. In some embodiments, the vaporizing may comprise heating the at least one reducing agent in a deposition chamber in which the vapor deposition process is performed. In some embodiments, the vaporizing may comprise heating a conduit for delivering the at least one reducing agent, the at least one reducing gas, or any combination thereof to, for example, a deposition chamber. In some embodiments, the vaporizing may comprise operating a vapor delivery system comprising the at least one reducing agent. In some embodiments, the vaporizing may comprise heating to a temperature sufficient to vaporize the at least one reducing agent to obtain the at least one reducing gas. In some embodiments, the vaporizing may comprise heating to a temperature below a decomposition temperature of at least one of the at least one reducing agent, the at least one reducing gas, or any combination thereof. In some embodiments, the at least one reducing agent may be present in a gas phase, in which case the step is optional and not required. For example, the at least one reducing agent may comprise the at least one reducing gas.

The at least one reducing agent, the at least one reducing gas, or any combination thereof may be selected to obtain a desired ruthenium-containing film. In some embodiments, the at least one reducing agent, the at least one reducing gas, or any combination thereof may comprise at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the method for making a ruthenium-containing film does not comprise use of oxygen. In some embodiments, the at least one reducing agent, the at least one reducing gas, or any combination thereof does not comprise oxygen. For example, in some embodiments, the at least one reducing agent, the at least one reducing gas, or any combination thereof does not comprise at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one reducing agent, the at least one reducing gas, or any combination thereof are present in a container or other vessel. The at least one reducing agent, the at least one reducing gas, or any combination thereof may be present as a solid, a liquid, a gas, a vapor, or any combination thereof.

The method for making a ruthenium-containing film 100 may comprise contacting 104 a first surface portion and a second surface portion of a substrate with the vaporized ruthenium precursor and at least one reducing gas.

In some embodiments, the contacting comprises contacting at least one of the vaporized ruthenium precursor, the at least one reducing gas, or any combination thereof, with the substrate, under vapor deposition conditions, sufficient to form a ruthenium-containing film on a select surface of the substrate. The contacting may be performed in any system, apparatus, device, assembly, chamber thereof, or component thereof suitable for vapor deposition processes, including, for example and without limitation, a deposition chamber, among others. In some embodiments, the method further comprises contacting at least one inert gas with the substrate. In some embodiments, the at least one inert gas comprises at least one of argon, helium, nitrogen, or any combination thereof.

In some embodiments, the contacting comprises bringing at least one of the vaporized ruthenium precursor, the at least one reducing gas, the at least one inert gas, or any combination thereof, into immediate or close proximity with the first surface portion and the second surface portion of the substrate. In some embodiments, the contacting comprises bringing at least one of the vaporized ruthenium precursor, the at least one reducing gas, the at least one inert gas, or any combination thereof, into direct contact with the first surface portion and the second surface portion of the substrate. In some embodiments, the contacting comprises flowing at least one of the vaporized ruthenium precursor, the at least one reducing gas, the at least one inert gas, or any combination thereof, into a chamber containing the substrate. In some embodiments, the contacting comprises pumping at least one of the vaporized ruthenium precursor, the at least one reducing gas, the at least one inert gas, or any combination thereof, into a chamber containing the substrate. In some embodiments, the contacting comprises injecting at least one of the vaporized ruthenium precursor, the at least one reducing gas, the at least one inert gas, or any combination thereof, into a chamber containing the substrate. In some embodiments, the contacting comprises introducing at least one of the vaporized ruthenium precursor, the at least one reducing gas, the at least one inert gas, or any combination thereof, into a chamber containing the substrate.

In some embodiments, the contacting comprises mixing at least one of the vaporized ruthenium precursor, the at least one reducing gas, the at least one inert gas, or any combination thereof to obtain at least one gas mixture. In some embodiments, for example, at least two of the vaporized ruthenium precursor, the at least one reducing gas, and the at least one inert gas are mixed and supplied to a deposition chamber via a gas line. In some embodiments, when one of the vaporized ruthenium precursor, the at least one reducing gas, or the at least one inert gas are not mixed, the unmixed gas and/or vapor species is supplied to a deposition chamber via another gas line. In other embodiments, the vaporized ruthenium precursor is supplied to a deposition chamber via a first gas line. In some embodiments, the at least one reducing gas is supplied to a deposition chamber via a second gas line. In some embodiments, the at least one inert gas is supplied to a deposition chamber via a third gas line. In some embodiments, the first gas line, the second gas line, and the third gas line are different.

The vaporized ruthenium precursor and the at least one reducing gas may be contacted with the substrate at different times. For example, each of the vaporized ruthenium precursor and the at least one reducing gas may be present in the deposition chamber with the substrate at different times. That is, in some embodiments, the contacting does not comprise contemporaneous contacting or simultaneous contacting of the vaporized ruthenium precursor and the at least one reducing gas with the substrate. In some embodiments, the contacting may comprise alternate and/or sequential contacting, in one or more cycles, of the vaporized ruthenium precursor with the substrate and subsequently contacting the at least one reducing gas with the substrate. For example, in some embodiments, the contacting may comprise one or more of the following steps: contacting the substrate with the vaporized ruthenium precursor in the deposition chamber; purging the deposition chamber (e.g., by flowing the at least one inert gas through the deposition chamber); contacting the substrate with the at least one reducing gas in the deposition chamber; and purging the deposition chamber (e.g., by flowing the at least one inert gas through the deposition chamber). In some embodiments, the vaporized ruthenium precursor and the at least one reducing gas are contacting with the substrate at the same time, either as a gas/vapor mixture or via separate gas lines.

The contacting may be performed at a deposition temperature. The deposition temperature may be a temperature less than the thermal decomposition temperature of at least one of the vaporized ruthenium precursor, the at least one reducing gas, or any combination thereof. The deposition temperature may be sufficiently high to reduce or avoid condensation of at least one of the vaporized ruthenium precursor, the at least one reducing gas, or any combination thereof. In some embodiments, the substrate may be heated to the deposition temperature. In some embodiments, the chamber or other vessel in which the substrate is contacted with the vaporized ruthenium precursor and the at least one reducing gas is heated to the deposition temperature. In some embodiments, at least one of the vaporized ruthenium precursor, the at least one reducing gas, or any combination thereof may be heated to the deposition temperature. The deposition temperature may be a temperature of 150° C. to 450° C., or any range or subrange between 150° C. and 450° C. In some embodiments, the deposition temperature may be a temperature of 150° C. to 425° C., 150° C. to 400° C., 150° C. to 375° C., 150° C. to 350° C., 150° C. to 325° C., 150° C. to 300° C., 150° C. to 275° C., 150° C. to 250° C., 150° C. to 225° C., 150° C. to 200° C., 150° C. to 175° C., 175° C. to 450° C., 200° C. to 450° C., 225° C. to 450° C., 250° C. to 450° C., 275° C. to 450° C., 300° C. to 450° C., 325° C. to 450° C., 350° C. to 450° C., 375° C. to 450° C., 400° C. to 450° C., or 425° C. to 450° C.

The contacting may be performed at a deposition pressure. In some embodiments, the deposition pressure may comprise a vapor pressure of at least one of the vaporized ruthenium precursor, the at least one reducing gas, or any combination thereof. In some embodiments, the deposition pressure may comprise a chamber pressure. The deposition pressure may be a pressure of 0.5 Torr to 100 Torr. For example, in some embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 0.5 Torr to 95 Torr, 0.5 Torr to 90 Torr, 0.5 Torr to 85 Torr, 0.5 Torr to 80 Torr, 0.5 Torr to 75 Torr, 0.5 Torr to 70 Torr, 0.5 Torr to 65 Torr, 0.5 Torr to 60 Torr, 0.5 Torr to 55 Torr, 0.5 Torr to 50 Torr, 0.5 Torr to 45 Torr, 0.5 Torr to 40 Torr, 0.5 Torr to 35 Torr, 0.5 Torr to 30 Torr, 0.5 Torr to 25 Torr, 0.5 Torr to 20 Torr, 0.5 Torr to 15 Torr, 0.5 Torr to 10 Torr, 0.5 Torr to 5 Torr, or 0.5 Torr to 1 Torr.

The first surface portion and the second surface portion of the substrate may be surface portions of an electronic device. In some embodiments, the electronic device is a partially completed electronic device (e.g., manufacturing/fabrication of the electronic device is started but not yet complete). In some embodiments, the electronic device is a completed electronic device (e.g., manufacturing/fabrication of the electronic device is complete or at least substantially complete). In some embodiments, the first surface portion and the second surface portion are surface portions of a gate-all-around transistor. In some embodiments, because the ruthenium-containing film is deposited during fabrication and/or manufacture of the gate-all-around transistor, the first surface portion and the second surface portion of the gate-all-around transistor may be surface portions of an incomplete gate-all-around transistor. That is, in some embodiments, the ruthenium-containing film is deposited on a surface portion of a partially constructed gate-all-around transistor. In some embodiments, the ruthenium-containing film is deposited on a surface portion of a fully constructed gate-all-around transistor. In some embodiments, the gate-all-around transistor—whether partially fabricated or completely fabricated—has a plurality of exposed surfaces (e.g., two exposed surfaces, up to hundreds of exposed surfaces), wherein at least two of the exposed surfaces is formed of a different chemical composition. Accordingly, it will be appreciated that the substrate may have more than the first surface portion and the second surface portion—that is, the substrate may have a plurality of surface portions (e.g., exposed surface portions).

In some embodiments, the first surface portion and the second surface portion can be any two surfaces of a partially constructed or fully constructed gate-all-around transistor. In some embodiments, the substrate is at least a portion of a gate-all-around transistor. The first surface portion and the second surface portion can have any spatial arrangement of any two surfaces of a gate-all-around transistor. In some embodiments, the first surface portion and the second surface portion are adjacent or proximal to each other. In some embodiments, the first surface portion abuts the second surface portion. In some embodiments, at least one of the first surface portion, the second surface portion, or any combination thereof, is a vertical surface portion. In some embodiments, at least one of the first surface portion, the second surface portion, or any combination thereof, is a horizontal surface portion. In some embodiments, at least one of the first surface portion, the second surface portion, or any combination thereof, is an angled surface portion (e.g., not a vertical surface portion and/or not a horizontal surface portion). In some embodiments, the first surface portion of the substrate is a first surface portion of a gate-all-around transistor; and the second surface portion of the substrate is a second surface portion of a gate-all-around transistor.

The first surface portion and the second surface portion of the substrate may be formed of different substances and/or different materials. In some embodiments, the ruthenium-containing film is deposited on the first surface portion. In some embodiments, the ruthenium-containing film is not deposited on the second surface portion. In some embodiments, the first surface portion of the substrate comprises or is formed of at least one of TaN, WCN, WN, TiN, Cu, W, Co, TaN, TiN, Mo, MoN, MoC, MoCN, DHF SiGe, SiGe, or any combination thereof. In some embodiments, the second surface portion of the substrate comprises or is formed of SiO₂ (e.g., a native silicon oxide), SiN, silicon, DHF silicon, SiCOH, low k dielectric, porous low k dielectrics, or any combination thereof. In some embodiments, the first surface portion of the substrate comprises or is formed of TaN and the second surface portion of the substrate comprises or is formed of SiN. In some embodiments, the first surface portion of the substrate comprises or is formed of WCN and the second surface portion of the substrate comprises or is formed of SiN. In some embodiments, the first surface portion of the substrate comprises or is formed of WN and the second surface portion of the substrate comprises or is formed of SiN. In some embodiments, the first surface portion of the substrate comprises or is formed of TiN and the second surface portion of the substrate comprises or is formed of SiN.

In some embodiments, the first surface portion of the substrate comprises or is formed of TaN and the second surface portion of the substrate comprises or is formed of SiO₂. In some embodiments, the first surface portion of the substrate comprises or is formed of WCN and the second surface portion of the substrate comprises or is formed of SiO₂. In some embodiments, the first surface portion of the substrate comprises or is formed of WN and the second surface portion of the substrate comprises or is formed of SiO₂. In some embodiments, the first surface portion of the substrate comprises or is formed of TiN and the second surface portion of the substrate comprises or is formed of SiO₂.

In some embodiments, the first surface portion of the substrate comprises or is formed of Cu and the second surface portion of the substrate comprises or is formed of SiN. In some embodiments, the first surface portion of the substrate comprises or is formed of W and the second surface portion of the substrate comprises or is formed of SiN. In some embodiments, the first surface portion of the substrate comprises or is formed of Co and the second surface portion of the substrate comprises or is formed of SiN. In some embodiments, the first surface portion of the substrate comprises or is formed of TaN and the second surface portion of the substrate comprises or is formed of SiN. In some embodiments, the first surface portion of the substrate comprises or is formed of WCN and the second surface portion of the substrate comprises or is formed of SiN. In some embodiments, the first surface portion of the substrate comprises or is formed of TiN and the second surface portion of the substrate comprises or is formed of SiN. In some embodiments, the first surface portion of the substrate comprises or is formed of Mo and the second surface portion of the substrate comprises or is formed of SiN.

In some embodiments, the first surface portion of the substrate comprises or is formed of Cu and the second surface portion of the substrate comprises or is formed of SiO₂. In some embodiments, the first surface portion of the substrate comprises or is formed of W and the second surface portion of the substrate comprises or is formed of SiO₂. In some embodiments, the first surface portion of the substrate comprises or is formed of Co and the second surface portion of the substrate comprises or is formed of SiO₂. In some embodiments, the first surface portion of the substrate comprises or is formed of TaN and the second surface portion of the substrate comprises or is formed of SiO₂. In some embodiments, the first surface portion of the substrate comprises or is formed of WCN and the second surface portion of the substrate comprises or is formed of SiO₂. In some embodiments, the first surface portion of the substrate comprises or is formed of TiN and the second surface portion of the substrate comprises or is formed of SiO₂. In some embodiments, the first surface portion of the substrate comprises or is formed of Mo and the second surface portion of the substrate comprises or is formed of SiO₂. In some embodiments, the first surface portion of the substrate is electrically conductive relative to the second surface portion of the substrate.

In some embodiments, the first surface portion of the substrate comprises or is formed of DHF SiGe or SiGe and the second surface portion of the substrate comprises or is formed of polysilicon (e.g., p-doped polysilicon). In some embodiments, the first surface portion of the substrate comprises or is formed of DHF SiGe or SiGe and the second surface portion of the substrate comprises or is formed of SiN. In some embodiments, the first surface portion of the substrate comprises or is formed of DHF SiGe or SiGe and the second surface portion of the substrate comprises or is formed of SiO₂. In some embodiments, the first surface portion of the substrate comprises or is formed of DHF SiGe or SiGe and the second surface portion of the substrate comprises or is formed of a thermal oxide. In some embodiments, the thermal oxide comprises TOₓ, where x is from 1 to 100. In some embodiments, at least one of the first surface portion, the second surface portion, or any combination thereof is a dilute hydrofluoric acid (DHF), e.g., 100:1 water:HF solution, cleaned surface. For example, in some embodiments, the first surface portion of the substrate comprises or is formed of DHF-cleaned SiGe. In some embodiments, the first surface portion of the substrate comprises or is formed of DHF-cleaned silicon. In some embodiments, the first surface portion of the substrate comprises or is formed of DHF-cleaned polysilicon (e.g., p-doped polysilicon).

In some embodiments, the first surface portion and the second surface portion are surface portions of a gate of a gate-all-around transistor. In some embodiments, the first surface portion of the gate comprises at least one of TaN, WCN, WN, TiN, or any combination thereof. In some embodiments, the second surface portion of the gate comprises at least one of SiO₂, SiN, or any combination thereof. In some embodiments, the first surface portion and the second surface portion are surface portions of a via of a gate-all-around transistor. In some embodiments, the first surface portion of the via comprises at least one of Cu, W, Co, TaN, WCN, TiN, Mo, MoN, MoC, MoCN, or any combination thereof. In some embodiments, the second surface portion of the via comprises at least one of SiN, SiO₂, or any combination thereof. In some embodiments, the first surface portion and the second surface portion are surface portions of a source and/or a drain of a gate-all-around transistor. In some embodiments, the first surface portion of the source and/or the drain comprises SiGe or DHF SiGe. In some embodiments, the second surface portion of the source and/or the drain comprises at least one of SiO₂, SiN, polysilicon, silicon, polysilicon/silicon, native silicon oxide, SiCOH, low k dielectric, porous low k dielectrics, or any combination thereof.

In some embodiments, the ruthenium is deposited on the first surface portion of the substrate with a selectivity of at least 40 Å relative to the second surface portion of the substrate. In some embodiments, the ruthenium is deposited on the first surface portion of the substrate with a selectivity of 25 Å to 80 Å, 25 Å to 75 Å, 25 Å to 70 Å, 25 Å to 65 Å, 25 Å to 60 Å, 25 Å to 55 Å, 25 Å to 50 Å, 25 Å to 45 Å, 40 Å to 80 Å, 40 Å to 75 Å, 40 Å to 70 Å, 40 Å to 65 Å, 40 Å to 60 Å, 40 Å to 55 Å, 40 Å to 50 Å, 40 Å to 45 Å, 45 Å to 80 Å, 50 Å to 80 Å, 55 Å to 80 Å, 60 Å to 80 Å, 65 Å to 80 Å, 70 Å to 80 Å, or 75 Å to 80 Å relative to the second surface portion of the substrate. In some embodiments, the ruthenium is deposited on the first surface portion of the substrate with a selectivity of up to 80 Å relative to the second surface portion of the substrate.

Some embodiments relate to a device. In some embodiments, the device comprises a ruthenium-containing film on a surface of a substrate. In some embodiments, the ruthenium-containing film comprises any film formed according to the methods disclosed herein. In some embodiments, the ruthenium-containing film comprises any film prepared from the ruthenium precursors disclosed herein. In some embodiments, for example and without limitation, the device comprises a substrate having a first surface portion and a second surface portion adjacent to the first surface portion. In some embodiments, a ruthenium layer located on the first surface portion of the substrate. In some embodiments, the ruthenium layer has a thickness of at least 25 Å on the first surface portion of the substrate. In some embodiments, the second surface portion of the substrate does not comprise ruthenium.

### Example 1

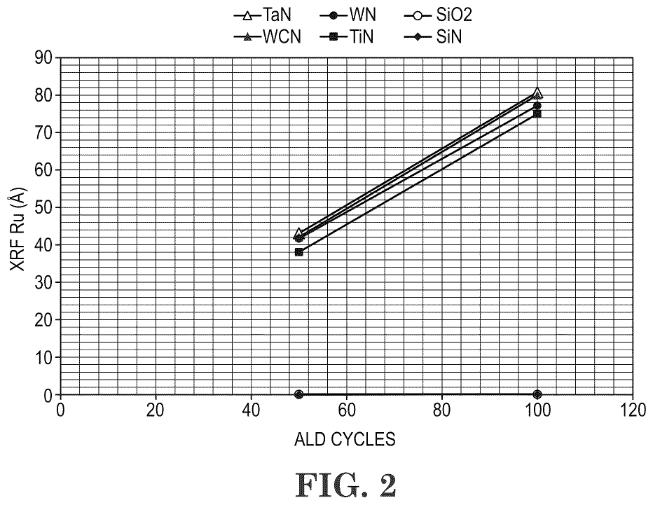

Examples 1 to 6 relate to PEALD Deposition of P-Cymene(1,3-Cyclohexadiene)Ru with NH₃ Pulse at 400 W Plasma Power, Cycle Pulse Sequence: (5-5-10-5) on a gate of a gate-all-around transistor. FIG. 2 is a graphical view of ruthenium film thickness versus atomic layer deposition cycle, according to some embodiments. As shown in FIG. 2, the ruthenium was selectively deposited on TaN, WCN, WN, and TiN relative to SiO₂ and SiN.

P-Cymene(1,3-Cyclohexadiene)Ru (P-cymene CHD Ru) was used. TaN was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 2, which is a graphical view of ruthenium film thickness versus atomic layer deposition cycle, according to some embodiments.

### Example 2

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. WCN was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used.

Throughout the cycle argon was flowed into the chamber at 610 sccm. The results are presented in FIG. 2, which is a graphical view of ruthenium film thickness versus atomic layer deposition cycle, according to some embodiments.

### Example 3

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. WN was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 2, which is a graphical view of ruthenium film thickness versus atomic layer deposition cycle, according to some embodiments.

### Example 4

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. TiN was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 2, which is a graphical view of ruthenium film thickness versus atomic layer deposition cycle, according to some embodiments.

### Example 5

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiO₂ was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 2, which is a graphical view of ruthenium film thickness versus atomic layer deposition cycle, according to some embodiments.

### Example 6

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiN was used as the substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 2, which is a graphical view of ruthenium film thickness versus atomic layer deposition cycle, according to some embodiments.

### Example 7

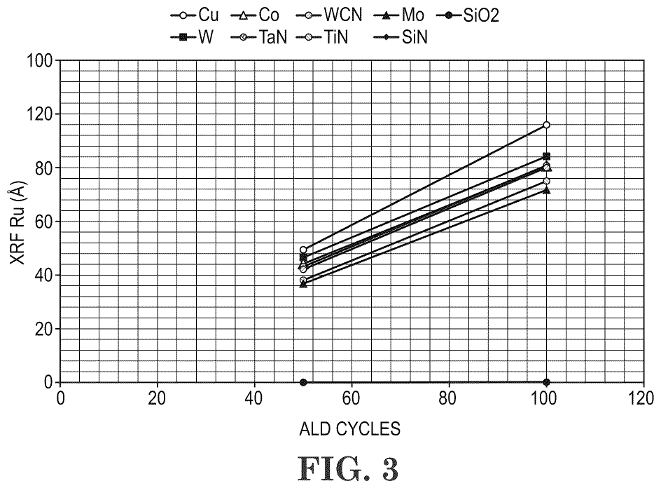

Examples 7 to 15 relate to PEALD Deposition of P-Cymene(1,3-Cyclohexadiene)Ru with NH₃ Pulse at 400 W Plasma Power, Cycle Pulse Sequence: (5-5-10-5) on a via of a gate-all-around transistor. FIG. 3 is a graphical view of ruthenium film thickness versus atomic layer deposition cycle, according to some embodiments. As shown in FIG. 3, the ruthenium was selectively deposited on Cu, W, Co, TaN, WCN, TiN, and Mo relative to SiO₂ and SiN.

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. Cu was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 8

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. W was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 9

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. Co was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 10

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. TaN was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 11

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. WCN was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 12

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. TiN was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 13

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. Mo was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 14

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiN was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 15

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiO₂ was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 3, which is a graphical view of ruthenium film thickness versus atomic layer deposition cycle, according to some embodiments.

### Example 16

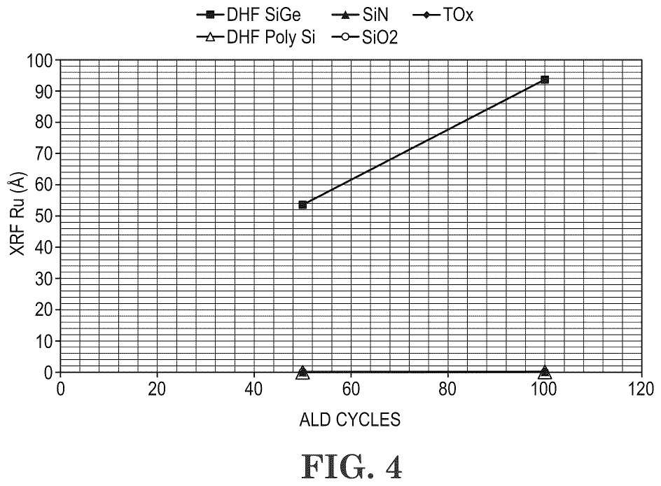

Examples 16 to 21 relate to PEALD Deposition of P-Cymene(1,3-Cyclohexadiene)Ru with NH₃ Pulse at 400 W Plasma Power, Cycle Pulse Sequence: (5-5-10-5) on a source-drain of a gate-all-around transistor. FIG. 4 is a graphical view of ruthenium film thickness versus atomic layer deposition cycle, according to some embodiments. As shown in FIG. 4, the ruthenium was selectively deposited on DHF SiGe relative to DHF polysilicon, SiN, SiO₂, and TOₓ, where x is 1 to 100.

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. DHF SiGe was used as a substrate for Ru deposition. A one-minute DHF (diluted hydrofluoric acid, 100:1) clean was used on SiGe prior to deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Example 17

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. P-doped polysilicon was used as a substrate for Ru deposition. A one-minute DHF (diluted hydrofluoric acid, 100:1) clean was used on P-doped polysilicon substrates prior to deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Example 18

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiN were used as substrates for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Example 19

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. SiO₂ (e.g., SiO₂ native oxide) was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Example 20

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. A thermal oxide (TOₓ) was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Example 21

PEALD Deposition of P-Cymene(1,3-Cyclohexadiene)Ru with NH₃ Pulse at 400 W Plasma Power, Cycle Pulse Sequence: (5-5-10-5). P-Cymene(1,3-Cyclohexadiene)Ru (P-cymene CHD Ru) was used. A silicon/polysilicon was used as a substrate for Ru deposition. The following PEALD deposition cycle was used: 5 second Ru precursor pulse; 5 second argon purge; 10 second ammonia (NH₃) plasma pulse; 5 second argon purge (5-5-10-5). Coupon temperature was 330° C. and a chamber pressure of 1 Torr was used. For Ru precursor delivery, an argon carrier flow rate of 250 sccm and an ampoule temperature of 100° C. were used. Throughout the cycle argon was flowed into the chamber at 610 sccm. The results are presented in FIG. 4, which is a graphical view of ruthenium film thickness versus atomic layer deposition cycle, according to some embodiments.

### Aspects

Various Aspects are described below. It is to be understood that any one or more of the features recited in the following Aspect(s) can be combined with any one or more other Aspect(s).

Aspect 1. A method comprising:
vaporizing at least a portion of a ruthenium precursor to produce a vaporized ruthenium precursor;
contacting a first surface portion and a second surface portion of a substrate with the vaporized ruthenium precursor and at least one reducing gas; and depositing ruthenium on the first surface portion of the substrate with a selectivity of at least 25 Å relative to the second surface portion of the substrate.

Aspect 2. The method of Aspect 1, wherein the first surface portion of the substrate comprises at least one of TaN, WCN, WN, TiN, Cu, W, Co, TaN, TiN, Mo, MoN, MoCN, DHF SiGe, SiGe or any combination thereof.

Aspect 3. The method of Aspect 1 or 2, wherein the second surface portion of the substrate comprises at least one of SiO₂, SiN, silicon, DHF silicon, native silicon oxide, SiCOH, SiOCNH, low k dielectric, porous low k dielectrics or any combination thereof.

Aspect 4. The method of any of Aspects 1-3, wherein the first surface portion comprises:
at least one of TaN, WCN, WN, TiN, or any combination thereof; and wherein the second surface portion comprises:
at least one of SiO2, SiN, SiOCNH, or any combination thereof.

Aspect 5. The method of Aspect 4, wherein the first surface portion is contacting the gate of a transistor and second surface portion isolates the gate electrically from other parts of the structure.

Aspect 6. The method of Aspect 4, wherein the first surface portion and the second surface portion are part of a gate-all-around (GAA) transistor.

Aspect 7. The method of any of Aspects 1-3,
wherein the first surface portion comprises:
at least one of Cu, W, Co, TaN, WCN, TiN, Mo, MoN, MoCN or any combination thereof; and
wherein the second surface portion of the via comprises SiN, SiO₂, or low K dielectric.

Aspect 8. The method of Aspect 7, wherein the first surface portion is at a bottom of a via structure and the second surface portion electrically isolates the via from other parts of the structure.

Aspect 9. The method of any of Aspects 1-3, wherein the first surface portion comprises DHF SiGe; or SiGe and wherein the second surface portion comprises at least one of SiO₂, SiN, DHF polysilicon/silicon, silicon, native silicon oxide, SiOCNH or any combination thereof.

Aspect 10. The method of Aspect 9, wherein the first surface portion and the second surface portion are part of a gate-all-around (GAA) transistor.

Aspect 11. The method of any of Aspects 1-10, wherein the depositing is performed at a temperature of at least 300° C. and a pressure of at least 0.5 Torr.

Aspect 12. The method of any of Aspects 1-11, wherein the depositing is performed at a temperature of 300° C. to 450° C. and a pressure of 0.5 Torr to 5 Torr.

Aspect 13. The method of any of Aspects 1-12, wherein the at least one reducing gas comprises NH₃.

Aspect 14. The method of any of Aspects 1-13, wherein the at least one reducing gas comprises H₂.

Aspect 15. The method of any of Aspects 1-14, wherein the depositing is performed in a chamber that is substantially free of oxygen.

Aspect 16. The method of any of Aspects 1-15, wherein the ruthenium is deposited on the first surface portion of the substrate with a selectivity of at least 40 Å relative to the second surface portion of the substrate.

Aspect 17. The method of any of Aspects 1-16, wherein the ruthenium is deposited on the first surface portion of the substrate with a selectivity of 40 Å to 80 Å relative to the second surface portion of the substrate.

Aspect 18. A device comprising:
a substrate having a first surface portion and a second surface portion adjacent to the first surface portion; and
a ruthenium layer located on the first surface portion of the substrate,
wherein the ruthenium layer has a thickness of at least 25 Å on the first surface portion of the substrate;
wherein the second surface portion of the substrate does not comprise ruthenium.

Aspect 19. The device of Aspect 18, wherein the first surface portion of the substrate comprises at least one of TaN, WCN, WN, TiN, Cu, W, Co, TaN, TiN, Mo, MoN, MoC, MoCN, DHF SiGe, SiGe or any combination thereof.

Aspect 20. The device of Aspect 18 or 19, wherein the second surface portion of the substrate comprises at least one of SiO₂, SiN, silicon, DHF silicon, native silicon oxide, SiCOH, SiOCNH, low k dielectric, porous low k dielectrics or any combination thereof.

Aspect 21. The device of any of Aspects 18-20,
wherein the first surface portion comprises:
at least one of TaN, WCN, WN, MoN, TiN, or any combination thereof; and
wherein the second surface portion comprises:
at least one of SiO2, SiN, or any combination thereof.

Aspect 22. The device of Aspect 21, wherein the first surface portion and the second surface portion are part of a gate-all-around (GAA) transistor.

Aspect 23. The device of any of Aspects 18-20,
wherein the first surface portion comprises:
at least one of Cu, W, Co, TaN, WCN, TiN, Mo, MoN, MoC, MoCN or any combination thereof;
wherein the second surface portion comprises SiO₂.

Aspect 24. The device of Aspect 23, wherein the first surface portion is at a bottom of a via structure and the second surface portion electrically isolates the via from other parts of the structure.

Aspect 25. The device of any of Aspects 18-20,
wherein the first surface portion comprises DHF SiGe, SiGe, or any combination thereof; and
wherein the second surface portion comprises at least one of SiO₂, SiN, DHF polysilicon/silicon, silicon, native silicon oxide, or any combination thereof.

Aspect 26. The device of Aspect 25, wherein the first surface portion and the second surface portion are part of a gate-all-around (GAA) transistor.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
vaporizing at least a portion of a ruthenium precursor to produce a vaporized ruthenium precursor;
contacting a first surface portion and a second surface portion of a substrate with the vaporized ruthenium precursor and at least one reducing gas; and
depositing ruthenium on the first surface portion of the substrate with a selectivity of at least 25 Å relative to the second surface portion of the substrate.

2. The method of claim 1, wherein the first surface portion of the substrate comprises at least one of TaN, WCN, WN, TiN, Cu, W, Co, TaN, TiN, Mo, MoN, MoCN, DHF SiGe, SiGe or any combination thereof.

3. The method of claim 1, wherein the second surface portion of the substrate comprises at least one of SiO₂, SiN, silicon, DHF silicon, native silicon oxide, SiCOH, SiOCNH, low k dielectric, porous low k dielectrics or any combination thereof.

4. The method of claim 1,
wherein the first surface portion comprises:
at least one of TaN, WCN, WN, TiN, or any combination thereof; and
wherein the second surface portion comprises:
at least one of SiO₂, SiN, SiOCNH, or any combination thereof.

5. The method of claim 4, wherein the first surface portion is contacting the gate of a transistor and second surface portion isolates the gate electrically from other parts of the structure.

6. The method of claim 4, wherein the first surface portion and the second surface portion are part of a gate-all-around (GAA) transistor.

7. The method of claim 1,
wherein the first surface portion comprises:
at least one of Cu, W, Co, TaN, WCN, TiN, Mo, MoN, MoCN or any combination thereof; and
wherein the second surface portion of the via comprises SiN, SiO₂, or low K dielectric.

8. The method of claim 7, wherein the first surface portion is at a bottom of a via structure and the second surface portion electrically isolates the via from other parts of the structure.

9. The method of claim 1,
wherein the first surface portion comprises DHF SiGe; or SiGe and
wherein the second surface portion comprises at least one of SiO₂, SiN, DHF polysilicon/silicon, silicon, native silicon oxide, SiOCNH or any combination thereof.

10. The method of claim 9, wherein the first surface portion and the second surface portion are part of a gate-all-around (GAA) transistor.

11. The method of claim 1, wherein the depositing is performed at a temperature of at least 300° C. and a pressure of at least 0.5 Torr.

12. The method of claim 1, wherein the depositing is performed at a temperature of 300° C. to 450° C. and a pressure of 0.5 Torr to 5 Torr.

13. The method of claim 1, wherein the at least one reducing gas comprises NH₃.

14. The method of claim 1, wherein the at least one reducing gas comprises H₂.

15. The method of claim 1, wherein the depositing is performed in a chamber that is substantially free of oxygen.

16. The method of claim 1, wherein the ruthenium is deposited on the first surface portion of the substrate with a selectivity of at least 40 Å relative to the second surface portion of the substrate.

17. The method of claim 1, wherein the ruthenium is deposited on the first surface portion of the substrate with a selectivity of 40 Å to 80 Å relative to the second surface portion of the substrate.

18. A device comprising:
a substrate having a first surface portion and a second surface portion adjacent to the first surface portion; and
a ruthenium layer located on the first surface portion of the substrate,
wherein the ruthenium layer has a thickness of at least 25 Å on the first surface portion of the substrate;
wherein the second surface portion of the substrate does not comprise ruthenium.

19. The device of claim 18, wherein the first surface portion of the substrate comprises at least one of TaN, WCN, WN, TiN, Cu, W, Co, TaN, TiN, Mo, MoN, MoC, MoCN, DHF SiGe, SiGe or any combination thereof.

20. The device of claim 18, wherein the second surface portion of the substrate comprises at least one of SiO₂, SiN, silicon, DHF silicon, native silicon oxide, SiCOH, SiOCNH, low k dielectric, porous low k dielectrics or any combination thereof.

21. The device of claim 18,
wherein the first surface portion comprises:
at least one of TaN, WCN, WN, MoN, TiN, or any combination thereof; and
wherein the second surface portion comprises:
at least one of SiO₂, SiN, or any combination thereof.

22. The device of claim 21, wherein the first surface portion and the second surface portion are part of a gate-all-around (GAA) transistor.

23. The device of claim 18,
wherein the first surface portion comprises:
at least one of Cu, W, Co, TaN, WCN, TiN, Mo, MoN, MoC, MoCN or any combination thereof;
wherein the second surface portion comprises SiO₂.

24. The device of claim 23, wherein the first surface portion is at a bottom of a via structure and the second surface portion electrically isolates the via from other parts of the structure.

25. The device of claim 18,
wherein the first surface portion comprises DHF SiGe, SiGe, or any combination thereof; and
wherein the second surface portion comprises at least one of SiO₂, SiN, DHF polysilicon/silicon, silicon, native silicon oxide, or any combination thereof.

26. The device of claim 25, wherein the first surface portion and the second surface portion are part of a gate-all-around (GAA) transistor.
